(19) United States
(12) Patent Application Publication
(10) Pub. No.: US 2012/0055564 A1
(43) Pub. Date: Mar. 8, 2012

(54) DOUBLE GLAZING WITH A HIGH PHOTOVOLTAIC OUTPUT

(75) Inventors: Philippe Edouard Gravisse, Paris (FR); Marc Schiffmann, Masserac (FR)

(73) Assignee: LABORATOIRE DE PHYSIQUE DU RAYONNEMENT ET DE LA LUMIERE

(21) Appl. No.: 13/201,147

(22) PCT Filed: Feb. 12, 2010
(86) PCT No.: PCT/EP2010/051810

§ 371 Date: Nov. 14, 2011

(30) Foreign Application Priority Data
Feb. 12, 2009 (FR) 0900634

(51) Int. Cl. H01L 31/0232

(52) U.S. Cl. 137/257; 136/259

(57) ABSTRACT

The present disclosure relates to a rack with double photovoltaic glazing including a frame with a rabbet, the rabbet containing at least two substantially parallel transparent sheets, i.e. a front sheet intended for receiving sunlight and a rear sheet, wherein the double-glazed rack includes photovoltaic cells located at the back of the rabbet and a coating made of a material forming a cascade of light.

### CROSS-REFERENCE TO RELATED APPLICATIONS

This application is a National Phase Entry of International Application No. PCT/EP2010/051810, filed on Feb. 12, 2010, which claims priority to French Patent Application Serial No. 0900634, filed on Feb. 12, 2009, both of which are incorporated by reference herein.

### BACKGROUND AND SUMMARY

The present invention concerns a double glazing with high photovoltaic output, intended notably for buildings.

U.S. Patent Publication No. 2008/289621A is known in the state of the art, describing a structure comprising an orientable elongated solar sensor forming a modular element for the construction of a building. U.S. Patent Publication No. 2008/236654A is also known, describing a building having outside windows coated with a photovoltaic film. International Patent Publication No. WO 06040514A describes a rack system including Venetian blinds, the slats of which are coated with photovoltaic sensors. International Patent Publication No. WO 05067060A describes another window solution including photovoltaic cells.

U.S. Patent Publication No. 2003/0010378 is also known, describing superposed glass sheets between which solar cells are arranged. A silicone frame ensures the spacing of the two glass sheets and the tightness of the assembly. U.S. Patent Publication No. 2005/0284516 also describes a module formed by two glazings between which an assembly of photovoltaic cells is arranged. German Patent Nos. DE 3,125,622 or DE 3,125,620 or International Patent Publication No. WO 2009/049048 describe similar structures. International Patent Publication No. WO 2008/110567 describes a module consisting of a glass sheet covering a series of photovoltaic cells. Between them, a layer of material containing one or more photoluminescent materials is inserted.

U.S. Patent Publication No. 2008/245411 describes a photovoltaic generating structure containing at least one stack of doped plates in which each plate contains one particular dopant. The light is diffused in the section and excites the peripheral cells. The incident light successively crosses a bandpass filter and then each of the layers and interacts with the dopants it contains, with absorption in the consecutive layers.

The present invention proposes a double glazing with high photovoltaic output intended notably for buildings, ensuring an acceptable transparency and including means of photovoltaic conversion not masking visibility.

For this purpose, the invention concerns, according to the most general acceptance thereof, a rack with double glazing, including a frame with a rabbet, said rabbet joining at least two roughly parallel transparent sheets, a front or outer sheet intended to receive the sunlight and a back or inner sheet, characterized in that the rack with double glazing contains photovoltaic cells situated at the bottom of the rabbet and a coating of a material forming a cascade of light. The front sheet preferably presents a dichroic coating. The front sheet advantageously includes optically active dopants forming a cascade of light.

According to one variant, the transparent sheets are treated to at least partially reflect the wavelengths in at least one of the bands ranging from 750 to 950 nm, 600 to 750 nm or 800 to 950 nm. According to another variant, the transparent sheets are treated to produce multiple internal reflections in the range of greater sensitivity of the photovoltaic cells. The photovoltaic cells are advantageously covered with a cascade of light.

### BRIEF DESCRIPTION OF THE FIGURES

Other advantages and characteristics of the invention will appear on reading the description which follows, referring to the attached figures wherein:

FIG. 1 represents a cutaway view of an embodiment of a rack with double glazing according to the invention;

FIG. 2 represents a cutaway view of an embodiment of a rack with double glazing according to the invention;

FIG. 3 illustrates the principle of the cascades of light;

FIG. 4 represents a partial view in 3D of an embodiment of a rack with double glazing according to the invention;

FIG. 5 represents a partial view in 3D of another embodiment of a rack with double glazing according to the invention; and

FIG. 6 represents a view of a rack with double glazing according to an embodiment.

### DETAILED DESCRIPTION

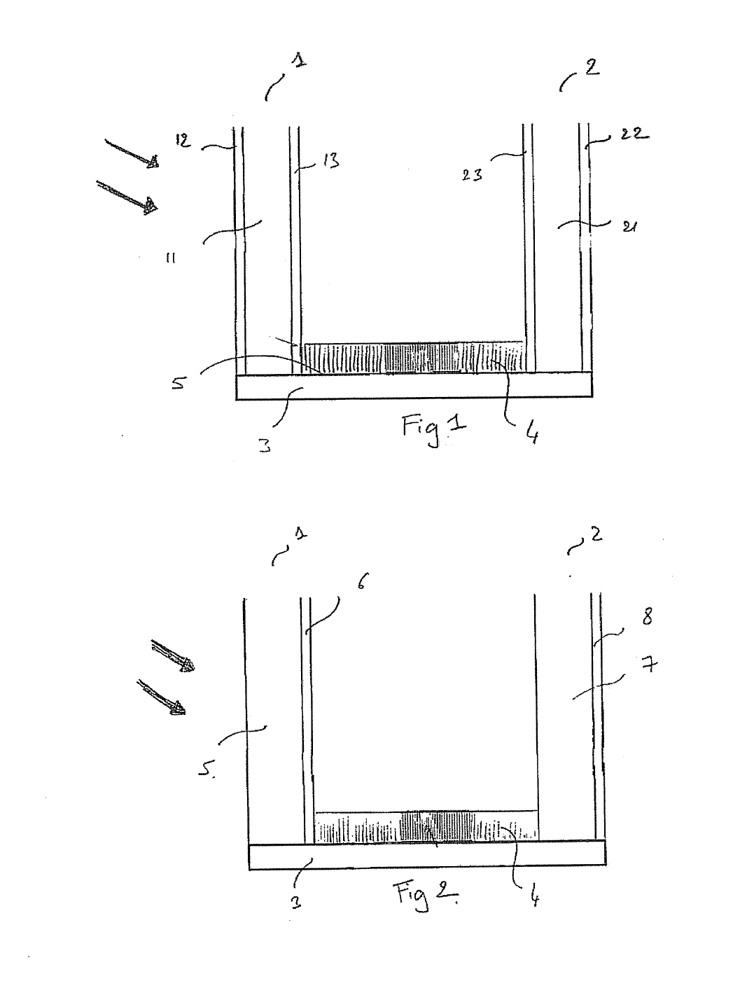

FIG. 1 represents an embodiment of a rack with double glazing according to the invention. It contains two sheets or glazings 1, 2 mounted on a frame or chassis 3 made, for example, of aluminum, PVC or wood. Photovoltaic cells or modules 4 are arranged on at least one part of the inner rabbet 5, perpendicular to the glazings. The width of the rabbet is dimensioned to make possible the positioning of cells of customary width. One alternative consists of placing ribbon-shaped cells 4 on the rabbet. Each of the glazings 1, 2 includes, for example, a pane (11, 21), typically 6 millimeters thick, for the outer glass 11 and 4 millimeters thick for the inner glass 21. In FIG. 1, the outer glazing 1 matches the glazing intended to receive sunlight symbolized by arrows.

According to an embodiment, each glass 11, 21 is covered on the outer or inner face with a coating forming a low-pass dichroic filter. In this example, for instance, the outer faces 12, 22 are the ones involved. This filter 12, 22 lets the light through in the solar spectrum useful for photoconversion. For example, for photovoltaic cells of multicrystalline or monocrystalline silicon type the transmission spectrum of the filter 12, 22 ranges between 300 and 950 nanometers. The filter 12, 22 is reflective for wavelengths exceeding 950 nanometers.

According to an embodiment, one of the faces of each glass (11, 21) further contains a doped coating 13, 23 formed by a transparent substrate, such as an acrylic resin with photoluminescent charges forming cascades of light, emission of the first corresponding to absorption of the second, the latter reemitting at a wavelength corresponding to the absorption of a third dopant, and so on.

FIG. 3 illustrates the principle of the cascades of light. Curve 31 represents the energy curve of the black body at 6000 K, curve 32 illustrates the solar radiation outside the atmosphere, curve 33 illustrates the solar radiation at sea level, curve 34 illustrates the solar radiation at sea level taking into account absorption due to water vapor as well as the presence of certain gases, curve 35 illustrates the spectral response of a monocrystalline or polycrystalline photovoltaic silicon (Si) cell and the zone 36 of the range of maximum spectral sensitivity of the monocrystalline or polycrystalline Si photocell. Curves 37 to 39 illustrate the absorption and emission curves of three photoluminescent charges of absorption peaks λₐ1, λₐ2, λₐ3, respectively, and of emission peaks λₑ1, λₑ2, λₑ3, respectively, in which emission of the first corresponds to absorption of the second, emission of the second corresponding to absorption of the third, whence the term cascade of light, making it possible to shift the solar spectrum to the range 36 of maximum spectral sensitivity of the monocrystalline or polycrystalline Si photocell.

According to an example, the cascades of light absorb the light in the range of 300 to 700 nanometers, and re-emit at a wavelength of approximately 950 nanometers. Alternatively, the coatings 13 and 23 form dichroic coatings and the coatings 12, 22 form cascades of light coatings. According to a variant, the dichroic coatings 13 and 23 and the cascade of light coatings 12 and 22 can be superposed on a same side of the glass walls to form a dual function coating: frequency shift by the material forming the cascade of light and near infrared reflector by the dichroic filter in order to trap the photons useful for the photovoltaic cells.

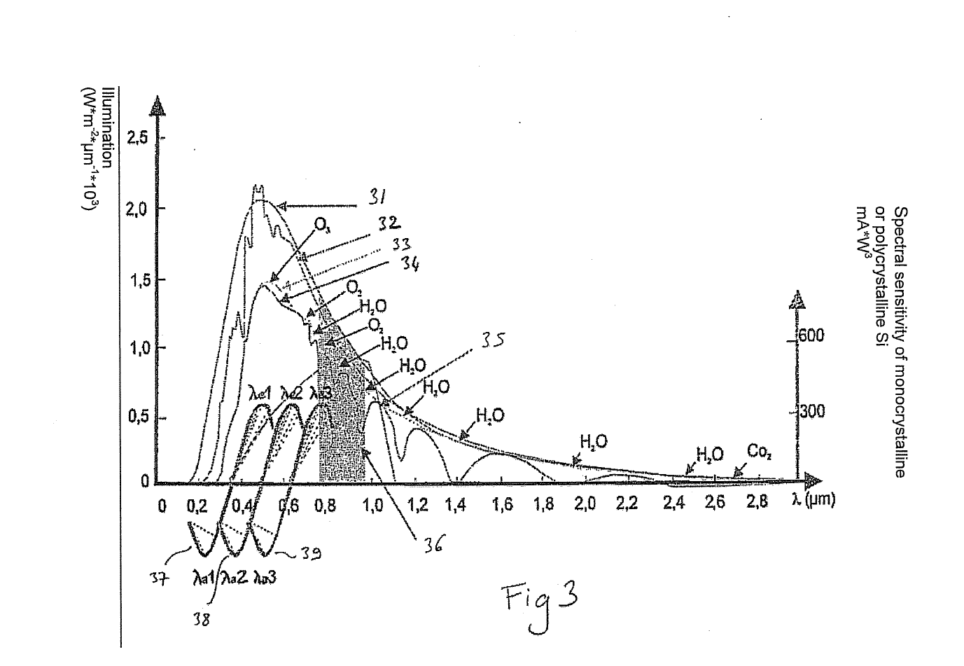

FIG. 2 represents a variant embodiment for a so-called curtain wall application. The rack with double glazing includes a sheet of glass 5 coated with a resin 6 doped with cascades of light. The back sheet of glass 7 is coated with a reflecting material 8. The photovoltaic cells 4 placed at the bottom of the rabbet collect the light diffused by the cascades of light.

According to an example, the sheet of glass 7 is replaced by a transparent PMMA plate (or equivalent material) doped with cascades of light. According to another variant, the glass sheet 7 is covered with a coating doped with cascades of light.

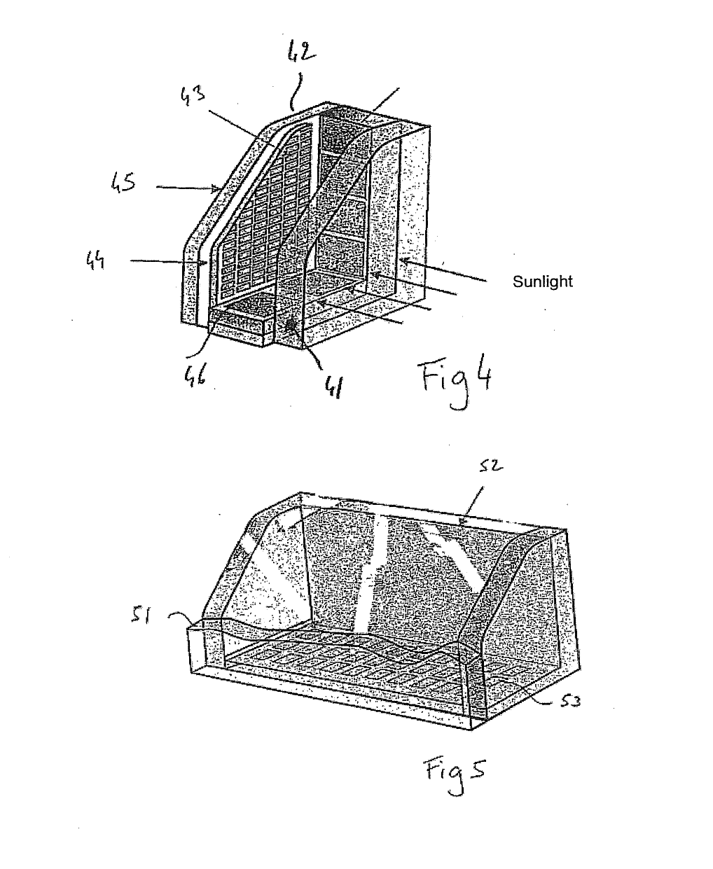

FIG. 4 represents a partial 3D view of an example of a photovoltaic rack according to the invention. In that example, the front face 41 is of dichroic type with cutoff, for example, at 800 nm. The back face 42 of the double glazing contains a photovoltaic module of the Schott Corporation's ASI Thru type, enabling light to pass through, a coating 44 of a material forming a cascade of light, reemitting, for example, in the 550-750 nm band, optimal range of sensitivity of the ASI Thru amorphous photovoltaic and a white reflecting and/or anti-stokes treated surface 45. The surface 45 can also be neutral in case of need to for sunlight to pass through partially. At the bottom of the double glazing rabbet, other photovoltaic cells 46 of ASI type are also arranged and can be coated with a material forming a cascade of light on re-emission in the 550-750 band in order to further improve the photocurrent output.

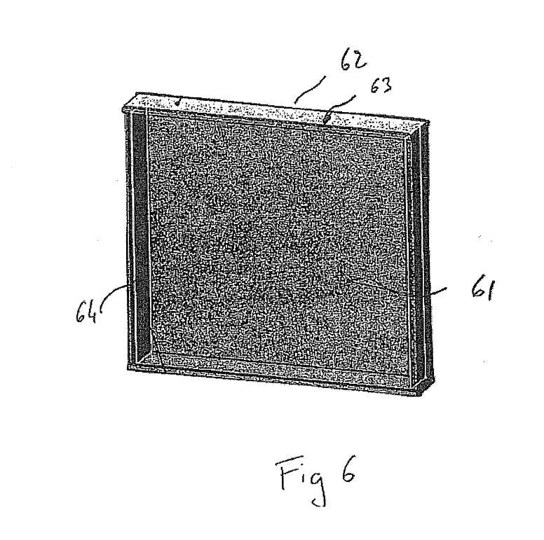

FIG. 5 presents another embodiment of a three-dimensional opto-photovoltaic rack with “monocrystalline or multicrystalline Si generator.” The front (or outer) glass 51 is, for example, dichroic with T%/R% cutoff at 1100 nm. The back (or inner) glass 52 is transparent, coated with a material forming a cascade of light reemitting in the 800-1000 nm band. The monocrystalline or multicrystalline Si photovoltaic modules 53 are placed at the bottom of the rabbet and can also be coated with a material forming a cascade of light of 800-1000 nm spectral re-emission type, corresponding to the range of greater sensitivity of the monocrystalline or multicrystalline cells.

These photovoltaic generator elements are perfectly integrated in periurban or very high buildings with the architecture for which they are intended. Furthermore, these modular generators can be interconnected with each other to obtain the PW power and V voltage desired. In such opto-photovoltaic generators, the different opto-electronic components are complementary and optimized and allow photoelectric gains by a factor of 2 compared to the standard generators with equal silicon surface, with everything otherwise being the same. The laboratory tests conducted have demonstrated the efficiency of 2D opto-photovoltaic systems and expected electric gains.

A geometric variant can be introduced in the system in the form of a modification of the size of the internal rabbet with double glazing in order to integrate there wider photovoltaic modules corresponding to certain commercial dimensions and then making possible a higher delivered electric power. Thus, a standard 6×16×4 mm double glazing with rabbet of 16 could pass 6×160×4 with photovoltaic module integrated in the 160-mm-wide rabbet, then producing a factor 10 delivered current relative to the initial photovoltaic double glazing.

Thus, in a double glazing type structure such as represented in FIG. 6, consisting of a front or outer pane 61, a back or inner pane 62, connected together by a section 63 providing a rabbet between the two panes, it is proposed that each element be arranged so that the new element thus made acquires, thanks to each of these new components, at least one of the following functions:

Photovoltaic conversion by the monocrystalline or multicrystalline amorphous silicon cells of modules 64 placed at the bottom of the rabbet or on the back face in the case of semitransparent modules of the Schott Corporation's ASI Thru type;

Light collector by diffusion and waveguide effect;

Transformer of the incident solar spectrum by effect of a “cascade of light” re-emitting in the range of greater sensitivity of the monocrystalline or multicrystalline amorphous Si cells;

Trapping of useful photons by multiple internal reflections in the band of greater spectral sensitivity of the photocells used;

Total reflection by polychromatic white reflector (placed on back face to form a curtain wall).

The element thus constituted retains its standard double glazing functions, to which the high output photovoltaic generator function is added. In fact, the double glazing structure constitutes an original and functional photovoltaic generator architecture, as previously described. These opto-electronic elements are made so that they respond electromagnetically and spectrally complete one another for the purpose of generating a high photoelectric current of factor 2 relative to an equivalent device whose components would not have been treated opto-electronically by cascades of light, dichroism, multichrome reflector and cells with spectral response for this entire three-dimensional opto-photovoltaic system.

Though described by a number of detailed embodiments, the rack with double glazing according to the invention embraces different variants, modifications and improvements which will appear evident to one skilled in the art, it being understood that these different variants, modifications and improvements form part of the scope of the invention, as defined in the following claims.

1. A rack with double photovoltaic glazing including a frame with a rabbet, the rabbet joining at least two roughly parallel transparent sheets, and a front or outer sheet intended to receive sunlight and a back or inner sheet, wherein the rack with double glazing contains photovoltaic cells situated at a bottom of the rabbet and a coating of a material forms a cascade of light.

2. The rack with double photovoltaic glazing according to claim 1, wherein at least one of the sheets has a low-pass dichroic coating.

3. The rack with double photovoltaic glazing according to claim 1, wherein the front sheet includes optically active dopants forming a cascade of light.

4. The rack with double photovoltaic glazing according to claim 1, wherein the transparent sheets are treated at the same time with cascades of light and dichroic coatings to at least partially reflect the wavelengths in at least one of the bands ranging from 750 to 950 nm, 600 to 750 nm or 800 to 950 nm, corresponding to the ranges of greater sensitivity of the photovoltaic cells.

5. The rack with double photovoltaic glazing according to claim 1, wherein the transparent sheets are treated to produce multiple internal reflections in the range of greater sensitivity of the photovoltaic cells.

6. The rack with double photovoltaic glazing according to claim 1, wherein the photovoltaic cells are coated with a material forming a cascade of light.

7. The rack with double photovoltaic glazing according to claim 1, wherein the back sheet is coated with a reflecting material.

8. A photovoltaic generator comprising:
first and second parallel optically transparent walls;
a frame comprising a rabbet engaged with the first and second parallel optically transparent walls; and
a photovoltaic cell positioned between the transparent walls and on the frame.

9. The photovoltaic generator according to claim 7, wherein one of the optically transparent walls comprises a low-pass dichroic coating.

10. The photovoltaic generator according to claim 8, wherein at least one transparent wall comprises an optically active dopant configured to absorb incident radiation having a first spectral density and emit radiation at a second spectral density.

11. The photovoltaic generator according to claim 10, wherein one of the transparent walls comprises a dichroic coating to at least partially reflect the wavelengths in at least one of the bands ranging from 750 to 950 nm, 600 to 750 nm or 800 to 950 nm, corresponding to ranges of greater sensitivity of the photovoltaic cell.

12. The photovoltaic generator according to claim 8, wherein the transparent walls have a dichroic coating configured to produce multiple internal reflections in the range of greater sensitivity of the photovoltaic cells.

13. The photovoltaic generator according to claim 8, wherein the first transparent layer has a plurality of active dopants, each active dopant configured to selectively absorb bands of electromagnetic radiation and emit radiation at a second band of radiation having a higher frequency.

14. The photovoltaic generator according to claim 8, wherein one of the transparent walls has a first optically active dopant, the first dopant is configured to absorb an electromagnetic wave at a first portion of the electromagnetic spectrum and emit an electromagnetic wave at a second portion of the electromagnetic spectrum, and the second portion of the electromagnetic spectrum is within a portion of the response curve for the photovoltaic cell.

15. The photovoltaic generator according to claim 14, wherein one of the transparent walls further comprises a second optically active dopant.

16. A photovoltaic generator comprising:
a photovoltaic cell;
first and second opposed transparent walls, the walls comprising a first optically active dopant configured to absorb an electromagnetic wave at a first portion of the electromagnetic spectrum and emit an electromagnetic wave at a second portion of the electromagnetic spectrum, the second portion of the electromagnetic spectrum being between a predetermined portion of a response curve for the photovoltaic cell; and
the photovoltaic cell being located between and perpendicular to the first and second opposed transparent walls.

17. The photovoltaic generator according to claim 16, further comprising at least one dichroic coating to at least partially reflect the wavelengths in at least one of the bands ranging from 750 to 950 nm, 600 to 750 nm or 800 to 950 nm, corresponding to the ranges of greater sensitivity of the photovoltaic cell.

18. The photovoltaic generator according to claim 16, wherein first and second opposed transparent walls further comprise a second optically active dopant.

19. The photovoltaic generator according to claim 16, further comprising a frame defining a rabbet joint, said photovoltaic cell being positioned on the frame.

20. The photovoltaic cell according to claim 16, wherein the transparent wall comprises a low-pass dichroic coating.
